(19) United States
(12) Patent Application Publication
(10) Pub. No.: US 2013/0319484 A1
(43) Pub. Date: Dec. 5, 2013

(54) SUBSTRATE TREATING APPARATUS AND SUBSTRATE TREATING METHOD

(71) Applicant: Semes Co., Ltd, Chungcheongnam-do (KR)

(72) Inventors: Yong-Hyoun CHOI, Chungcheongnam-do (KR); Jung-Sun PARK, Chungcheongnam-do (KR); Pil-Kyun HEO, Chungcheongnam-do (KR)

(21) Appl. No.: 13/907,043

(22) Filed: May 31, 2013

(30) Foreign Application Priority Data
May 31, 2012 (KR) 10-2012-0058389
Aug. 27, 2012 (KR) 10-2012-0093803

(51) Int. Cl. H01L 21/67

(52) U.S. Cl. CPC H01L 21/67034
USPC 134/109

(57) ABSTRACT

Provided is a substrate treating apparatus. The substrate treating apparatus includes a container providing a space in which a supercritical fluid flows or is received, a recovery tube having one end connected to the container to discharge the supercritical fluid within the container, the recovery tube including a valve, and a waste tube connected to the container to discharge the supercritical fluid within the container, the waste tube including a safety valve. The recovery tube having the other end connected to a recovery container in which the supercritical fluid discharged from the container is received for reusing.

### CROSS-REFERENCE TO RELATED APPLICATIONS

This U.S. non-provisional patent application claims priority under 35 U.S.C. §119 of Korean Patent Application Nos. 10-2012-0058389, filed on May 31, 2012, and 10-2012-0093803, filed on Aug. 27, 2012, the entire contents of which are hereby incorporated by reference.

### BACKGROUND OF THE INVENTION

The present disclosure herein relates to an apparatus and method for treating a substrate, and more particularly, to an apparatus and method for treating a substrate using a supercritical fluid.

Semiconductor devices are manufactured through various processes including a photolithography process in which a circuit pattern is formed on a substrate such as a silicon wafer. While the semiconductor devices are manufactured, various foreign substances such as particles, organic contaminants, metal impurities, and the like may be generated. These foreign substances may cause substrate defects to directly exert a bad influence on performance and yield of semiconductor devices. Thus, a cleaning process for removing the foreign substances may be essentially involved in a semiconductor device manufacturing process.

The cleaning process includes a chemical process of removing foreign substances on a substrate, a washing process of washing chemicals by using deionized (DI) water, and a drying process of drying the substrate. Typical drying processes are performed by replacing the DI water existing on the substrate with an organic solvent such as isopropyl alcohol (IPA) to evaporate the IPA.

However, such a drying process may cause pattern collapse as ever in a semiconductor device having a fine circuit pattern with a line width of about 30 nm or less even though the organic solvent is used. Thus, the current trend is an increase in replacement of the existing drying process with a supercritical drying process.

### SUMMARY OF THE INVENTION

The present invention also provides a substrate treating apparatus that is capable of efficiently performing a drying process by using a supercritical fluid.

The present invention also provides a substrate treating apparatus having improved recycling efficiency of a supercritical fluid.

Embodiments of the present invention provide substrate treating apparatuses including: a container providing a space in which a supercritical fluid flows or is received; a recovery tube having one end connected to the container to discharge the supercritical fluid within the container, the recovery tube including a valve; and a waste tube connected to the container to discharge the supercritical fluid within the container, the waste tube including a safety valve, wherein the recovery tube having the other end connected to a recovery container in which the supercritical fluid discharged from the container is received for reusing.

In some embodiments, the valve of the recovery tube may be different from the safety valve of the waste tube.

In other embodiments, the safety valve may include: a valve housing connected to the waste tube, the valve housing including an inlet through which the supercritical fluid is introduced and an outlet through which the supercritical fluid is discharged; an elastic member disposed in a cylinder that is provided within the valve housing; and a piston disposed between the elastic member and the inlet to open or close the safety valve while moving by the elastic member or a pressure of the supercritical fluid.

In still other embodiments, a packing preventing the supercritical fluid from leaking between the piston and an inner wall of the valve housing may be disposed on the inner wall of the valve housing.

In even other embodiments, the packing may include a viton.

In yet other embodiments, the valve disposed in the recovery tube may be provided in a diaphram type.

In further embodiments, the recovery container may separate foreign substances from the supercritical fluid received therein.

In still further embodiments, the recovery container may be connected to a supercritical fluid supply unit that supplies the supercritical fluid into a housing providing a space in which a substrate is treated.

In even further embodiments, the recovery tube may include: a main recovery tube having one end connected to the recovery container; and first and second lines branched from the other end of the main recovery tube in parallel, the first and second lines each being connected to the container.

In yet further embodiments, the valve may include a first valve disposed in the first line and a second valve disposed in the second line.

In much further embodiments, the container may include a housing providing a space in which a substrate is treated.

In still much further embodiments, the container may include a supercritical fluid supply unit that supplies the supercritical fluid into a housing providing a space in which a substrate is treated.

In even much further embodiments, the container may include a tube connecting a housing providing a space in which a substrate is treated to a supercritical fluid supply unit that supplies the supercritical fluid into the housing.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a plan view of a substrate treating apparatus according to an embodiment of the present invention;

FIG. 2 is a cross-sectional view of a first process chamber of FIG. 1;

FIG. 3 is a view illustrating a phase transition of carbon dioxide;

FIG. 4 is a view illustrating a tube of a second process chamber of FIG. 1;

FIG. 5 is a view illustrating circulation of a supercritical fluid;

FIG. 6 is a view illustrating tubes of a second process chamber according to another embodiment;

FIG. 7 is a view of a vent unit according to an embodiment of the present invention;

FIG. 8 is a cross-sectional view of a safety valve;

FIG. 9 is a view of a state in which the safety valve is opened;

FIG. 10 is a cross-sectional view of a portion at which the safety valve and a waste tube are connected to each other; and

FIG. 11 is a view of a state in which the vent unit is connected.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the thicknesses of layers and regions are exaggerated for clarity.

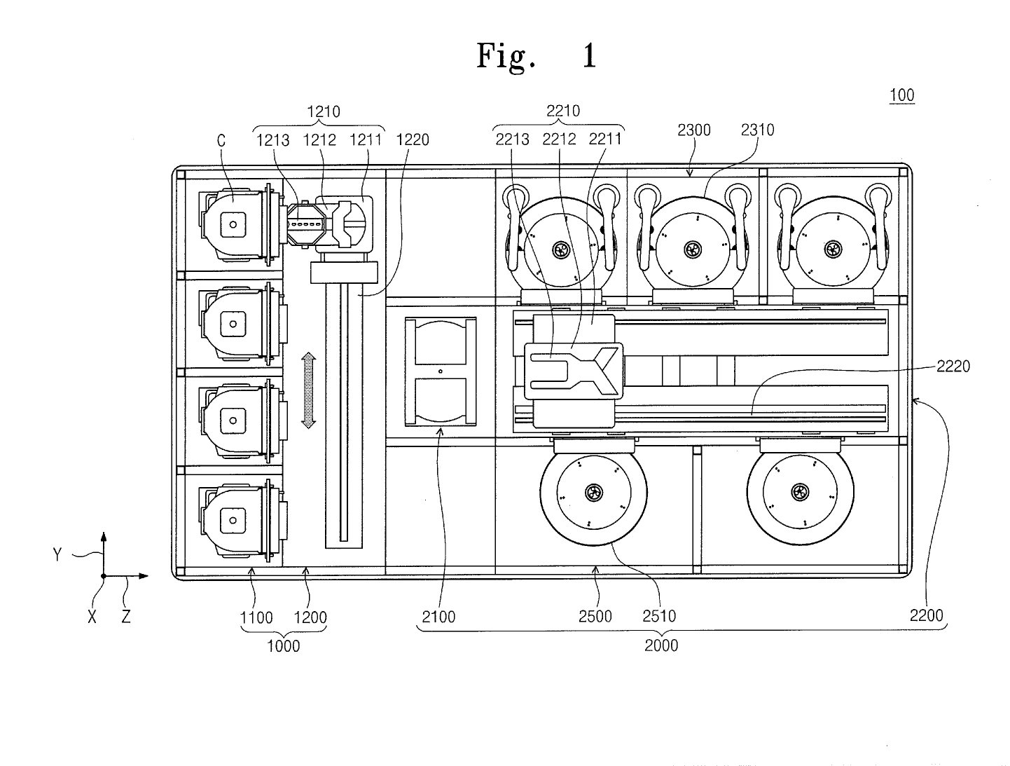

FIG. 1 is a plan view of a substrate treating apparatus according to an embodiment of the present invention.

Referring to FIG. 1, a substrate treating apparatus 100 includes an index module 1000 and a process module 2000.

The index module 1000 may be an equipment front end module (EFEM). Also, the index module 1000 includes a load port and a transfer frame 1200. The index module 1000 receives a substrate S from the outside to provide the substrate S into the process module 2000.

The load port 1100, the transfer frame 1200, and the process module 2000 may be successively arranged in a line. Here, a direction in which the load port 1100, the transfer frame 1200, and the process module 2000 are arranged is referred to as a first direction X. Also, when viewed from an upper side, a direction perpendicular to the first direction X is referred to as a second direction Y, and a direction perpendicular to the first and second directions X and Y is referred to as a third direction Z.

At least one load port 1100 may be provided in the index module 1000.

The load port 1100 is disposed on a side of the transfer frame 1200. When the load port 1100 is provided in plurality, the plurality of load ports 1100 may be arranged in a line along the second direction Y. The number and arrangement of load ports 1100 are not limited to the above-described example. For example, the number and arrangement of load ports 1100 may be changed according to a foot print, process efficiency, and arrangement with respect to the other substrate treating apparatuses 100. A carrier C in which the substrate C is received is disposed on the load port 1100. The carrier C is transferred from the outside and then loaded on the load port 1100, or is unloaded from the load port 1100 and then transferred into the outside. For example, the carrier C may be transferred between the substrate treating apparatuses 100 by a transfer unit such as an overhead hoist transfer (OHT). Here, the substrate S may be transferred by other transfer units such as an automatic guided vehicle, a rail guided vehicle, and the like, instead of the OHT, or a worker.

The substrate S is received into the carrier C. A front opening unified pod (FOUP) may be used as the carrier C. At least one slot supporting an edge of the substrate S may be disposed within the carrier C. When a plurality of slots are provided, the plurality of slots may be spaced apart from each other along the third direction Z. Thus, the substrate S may be placed within the carrier C. For example, the carrier C may receive twenty-five substrates S. The inside of the carrier C may be isolated from the outside by an openable door and thus be sealed. Thus, it may prevent the substrate S received in the carrier C from being contaminated.

The transfer module 1200 includes an index robot 1210 and an index rail 1220. The transfer frame 1200 transfers the substrate S between the carrier C seated on the load port 1100 and the process module 2000.

The index rail 1220 provides a moving path of the index robot 1210.

The index rail 1220 may be disposed in a length direction thereof parallel to the second direction Y. The index robot 1210 transfers the substrate S.

The index robot 1210 may include a base 1211, a body 1212, and an arm 1213. The base 1211 is disposed on the index rail 1220. Also, the base 1211 may be moved along the index rail 1220. The body 1212 is coupled to the base 1211. Also, the body 1212 may be moved along the third direction Z on the base 1211 or rotated around an axis defined in the third direction Z. The arm 1213 is disposed on the body 1212. Also, the arm 1213 may be moved forward and backward. A hand may be disposed on an end of the arm 1213 to pick up or place the substrate S. The index robot 1210 may include one or a plurality of arms 1213. When the plurality of arms 1213 are provided, the plurality of arms 1213 may be stacked on the body 1212 and arranged in the third direction Z. Here, the plurality of arms 1213 may be independently operated. Thus, in the index robot 1210, the base 1211 may be moved in the second direction Y on the index rail 1220. Also, the index robot 1210 may take the substrate S out of the carrier C to transfer the substrate S into the process module 2000 or take the substrate S out of the process module 2000 to receive the substrate S into the carrier C.

Also, the index rail 1220 may be omitted in the transfer frame 1200, and the index robot 1210 may be fixed to the transfer frame 1200. In this case, the index robot 1210 may be disposed on a central portion of the transfer frame 1200.

The process module 2000 includes a buffer chamber 2100, a transfer chamber 2200, a first process chamber 2300, and a second process chamber 2500. The process module 2000 receives the substrate S from the index module 1000 to perform a cleaning process on the substrate S. The buffer chamber 2100 and the transfer chamber 2200 are disposed along the first direction X, and the transfer chamber 2200 is disposed in a length direction thereof parallel to the first direction X. The process chambers 2300 and 2500 may be disposed on a side surface of the transfer chamber 2200 in the second direction Y. Here, the first process chamber 2300 may be disposed on one side of the transfer chamber 2200 in the second direction Y, and the second process chamber 2500 may be disposed on the other side opposite to the one side on which the first process chamber is disposed. The first process chamber 2300 may be provided in one or plurality. When the plurality of first process chambers 2300 are provided, the first process chambers 2300 may be disposed on one side of the transfer chamber 2200 along the first direction X, stacked along the third direction Z, or disposed in combination thereof. Also, the second process chamber 2500 may be provided in one or plurality. When the plurality of second process chambers are provided, the second process chambers may be disposed along the first direction X on the other side of the transfer chamber 2500, stacked along the third direction Z, or disposed in combination thereof.

However, the arrangement of each of the chambers 2100, 2200, and 2500 in the process module 2000 is not limited to the above-described example. That is, the chambers 2100, 2200, and 2500 may be adequately disposed in consideration of process efficiency. For example, as necessary, the first and second process chambers 2300 and 2500 may be disposed along the first direction X on the same side surface as the transfer module 2200 or stacked on each other.

The buffer chamber 2100 is disposed between the transfer frame and the transfer chamber 2200. The buffer chamber 2100 provides a buffer space in which the substrate S transferred between the index module 1000 and the process module 2000 temporarily stays. At least one buffer slots on which the substrate S is placed may be provided within the buffer chamber 2100. When a plurality of buffer slots are provided, the plurality of buffer slots may be spaced apart from each other along the third direction Z. The substrate S taken out of the carrier C by the index robot 1210 may be seated on the buffer slot, or the substrate C transferred from the process chambers 2300 and 2500 by the transfer robot 2210 of the transfer chamber 2200 may be seated on the buffer slot. Also, the index robot 1210 or the transfer robot 2210 may take the substrate S out of the buffer slot to receive the substrate S into the carrier C or transfer the substrate S into the process chambers 2300 and 2500. The transfer chamber 2200 transfers the substrate S between the chambers 2100, 2300, and 2500 disposed therearound. The buffer chamber 2100 may be disposed on one side of the transfer chamber 2200 in the first direction X. The process chambers 2300 and 2500 may be disposed on one side or both sides of the transfer chamber 2200 in the second direction Y. Thus, the transfer chamber 2200 may transfer the substrate S between the buffer chamber 2100, the first process chamber 2300, and the second process chamber 2500. The transfer chamber 2200 includes a transfer rail 2220 and a transfer robot 2210.

The transfer rail 2220 provides a moving path of the transfer robot 2210. The transfer rail 2220 may be disposed parallel to the first direction X. The transfer robot 2210 transfers the substrate S. The transfer robot 2210 may include a base 2211, a body 2212, and an arm 2213. Since each component of the transfer robot 2210 is similar to that of the index robot 1210, detailed descriptions thereof will be omitted. The transfer robot 2210 transfers the substrate S between the buffer chamber 2100, the first process chamber 2300, and the second process chamber 2500 by operations of the body 2212 and the arm 2213 while the base 2211 is moved along the transfer rail 2220.

The first and second process chambers 2300 and 2500 may perform processes different from each other on the substrate S. Here, a first process performed in the first process chamber 2300 and a second process performed in the second process chamber 2500 may be successively performed. For example, a chemical process, a cleaning process, and a first drying process may be performed in the first process chamber 2300. Also, a second drying process as a subsequent process of the first process may be performed in the second process chamber 2500. Here, the first drying process may be a wet drying process performed using an organic solvent, and the second drying process may be a supercritical drying process performed using a supercritical fluid. As necessary, only one of the first and second drying processes may be selectively performed.

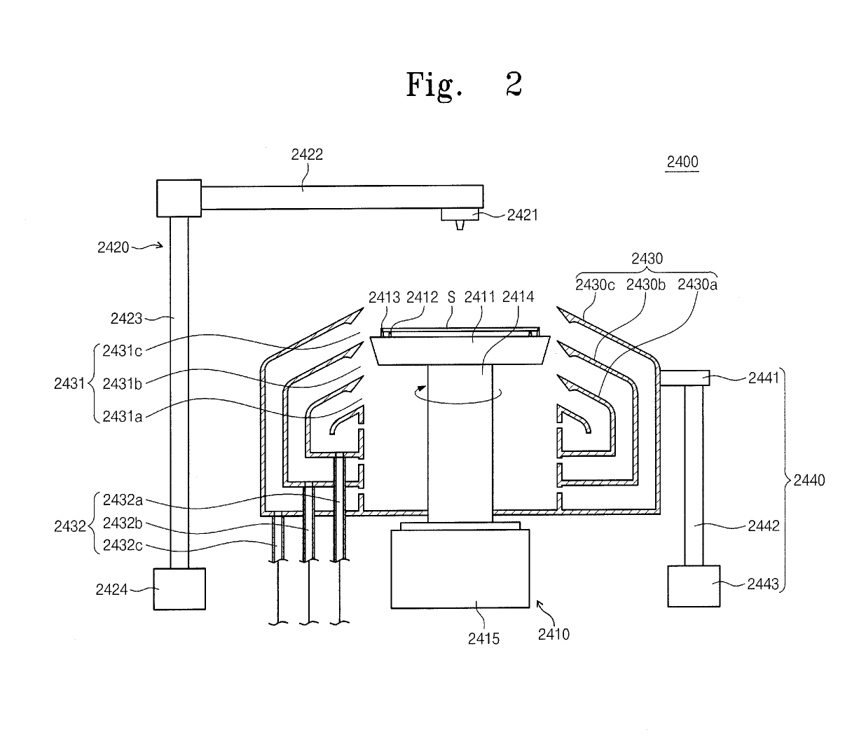

FIG. 2 is a cross-sectional view of a first process chamber of FIG. 1.

Referring to FIGS. 1 and 2, the first process chamber 2300 includes a housing 2310 and a process unit 2400. The first process is performed in the first process chamber 2300. Here, the first process may include at least one of the chemical process, the cleaning process, and the first drying process. As described above, the first drying process may be omitted.

The housing 2310 defines an outer wall of the first process chamber 230, and the process unit 2400 is disposed within the housing 2310 to perform the first process. The process unit 2400 includes a spin head 2410, a fluid supply member 2420, a recovery container 2430, and an elevation member 2440.

The substrate S is seated on the spin head 2410. Also, the spin head 2410 rotates the substrate S while processes are performed. The spin head 2410 may include a support plate 2411, a support pin 2412, a chucking pin 2413, a rotation shaft 2414, and a motor 2415.

The support plate 2411 has an upper portion having a shape similar to that of the substrate S. That is, the upper portion of the support plate 2411 may have a circular shape. The plurality of support pins 2412 on which the substrate S is placed and the plurality of chucking pins 2413 for fixing the substrate S are disposed on the support plate 2411. The rotation shaft 2414 rotated by the motor 2415 is fixed and coupled to a bottom surface of the support plate 2411. The motor 2415 generates a rotation force by using an external power source to rotate the support plate 2411 through the rotation shaft 2414. Thus, the substrate S may be seated on the spin head 2410, and the support plate 2411 may be rotated to rotate the substrate S while the first process is performed.

Each of the support pins 2412 protrudes from a top surface of the support plate 2411 in the third direction Z. The plurality of support pins 2412 are disposed spaced a preset distance apart from each other. When viewed from an upper side, the support pins 2412 may be arranged in a circular ring shape. A back surface of the substrate S may be placed on the support pins 2412. Thus, the substrate S is seated on the support pins 2412 so that the substrate S is spaced a protruding distance of each of the support pins 2412 spaced apart from the top surface of the support plate 2411 by the support pins 2412.

Each of the chucking pins 2413 may further protrude from the top surface of the support plate 2411 than each of the support pins 2412 in the third direction Z. Thus, the chucking pins 2413 may be disposed farther away from a center of the support plate 2411 than the support pins 2412. The chucking pins 2413 may be moved between a fixed position and a pick-up position along a radius direction of the support plate 2411. Here, the fixed position represents a position spaced a distance corresponding to a radius of the substrate S from the center of the support plate 2411, and the pick-up position represents a position away from the center of the support plate 2411 than the fixed position. The chucking pins 2413 are disposed at the pick-up position when the substrate S is loaded on the spin head 2410 by the transfer robot 2210. When the substrate S is loaded and then the process is performed, the chucking pins 2413 may be moved to the fixed position to contact a side surface of the substrate S, thereby fixing the substrate S in position. Also, when the process is finished and then the transfer robot 2210 picks the substrate S up to unload the substrate S, the chucking pins 2413 may be moved again to the pick-up position. Thus, the chucking pins 2413 may prevent the substrate S from being separated from the regular position by the rotation force when the spin head 2410 is rotated.

The fluid supply member 2420 may include a nozzle 2421, a support 2422, a support shaft 2423, and a driver 2424. The fluid supply member 2420 supplies a fluid onto the substrate S.

The support shaft 2423 is disposed so that a length direction thereof is parallel to the third direction Z. The driver 2424 is coupled to a lower end of the support shaft 2423. The driver 2424 rotates the support shaft 2423 or vertically moves the support shaft 2423 along the third direction Z. The support 2422 is vertically coupled to an upper portion of the support shaft 2423. The nozzle 2421 is disposed on a bottom surface of an end of the support 2422. The nozzle 2421 may be moved between a process position and a standby position by the rotation and elevation of the support shaft 2423 through the driver 2424. Here, the process position represents a position at which the nozzle 2421 is disposed directly above the support plate 2411, and the standby position represents a position at which the nozzle 2421 is disposed deviational from the direct upper side of the support plate 2411.

At least one fluid supply member 2420 may be provided in the process unit 2400. When the fluid supply member 2420 is provided in plurality, the plurality of fluid supply members 2420 may supply fluids different from each other, respectively. For example, each of the plurality of fluid supply members 2420 may supply a detergent, a rinsing agent, or an organic solvent. Here, a hydrogen (H₂0₂) solution, a solution in which ammonia (NH₄0H), hydrochloric acid (HCl), or sulfuric acid (H₂S0₄) is mixed with the hydrogen (H₂0₂) solution, or a hydrofluoric acid solution may be used as the detergent. Also, deionized (DI) water may be used as the rinsing agent, and isopropyl alcohol may be used as the organic solvent. Also, isopropyl alcohol, ethyl glycol, 1-propanol, tetrahydraulic franc, 4-hydroxyl, 4-methyl, 2-pentanone, 1-butanol, 2-butanol, methanol, ethanol, n-propyl alcohol, or dimethylether may be used as the organic solvent. For example, a first fluid supply member 2420a may spray the ammonia hydrogen peroxide solution, the second fluid supply member may spray the deionized water, and the third fluid supply member 2420c may spray an isopropyl alcohol solution.

When the substrate S is seated on the spin head 2410, the fluid supply member 2420 may be moved from the standby position to the process position to supply the fluid onto the substrate S. For example, the fluid supply part may supply the detergent, the rinsing agent, and the organic solvent to perform the chemical process, the cleaning process, and the first drying process, respectively. As described above, the spin head 2410 may be rotated by the motor 2415 to uniformly supply the fluids onto a top surface of the substrate S during the progression of the processes.

The recovery container 2430 provides a space in which the first process is performed. Also, the recovery container 2430 recovers the fluid used for the first process. When viewed from an upper side, the recovery container 2430 is disposed around the spin head 2410 to surround the spin head 2410 and has an opened upper side. At least one recovery container 2430 may be provided in the process unit 2400. Hereinafter, the process unit 2400 including three recovery containers 2430, i.e., a first recovery container 2430a, a second recovery container 2430b, and a third recovery container 2430c will be described as an example. However, the number of recovery containers 2430 may be differently selected according to the number of fluids and conditions of the first process.

Each of the first recovery container 2430a, the second recovery container 2430b, and the third recovery container 2430c may have a circular ring shape surrounding the spin head 2410. The first recovery container 2430a, the second recovery container 2430b, and the third recovery container 2430c may successively disposed away from a center of the spin head 2410. That is, the first recovery container 2430a surrounds the spin head 2410, the second recovery container 2430b surrounds the first recovery container 2430a, and the third recovery container 2430c surrounds the second recovery container 2430b. The first recovery container 2430a has a first inflow hole 2431a defined by an inner space thereof. The second recovery container 2430b has a second inflow hole 2431b defined by a space between the first recovery container 2430a and the second recovery container 2430b. The third recovery container 2430c has a third recovery container 2430c defined by a space between the second recovery container 2430b and the third recovery container 2430c. A recovery line 2432 extending downward along the third direction Z is connected to a bottom surface of each of the first, second, and third recovery container 2430a, 2430b, and 2430c. Each of the first, second, and third recovery lines 2432a, 2432b, and 2432c ventilates the fluids recovered into the first, second, and third recovery container 2430a, 2430b, and 2430c to supply the fluids into an external fluid recycling system (not shown). The fluid recycling system (not shown) may recycle the recovered fluids to reuse the fluids.

The elevation member 2440 includes a bracket 2441, an elevation shaft 2442, and an elevator 2443. The elevation member 2440 moves the recovery container 2430 in the third direction Z. The inflow hole 2421 of any one recovery container 2430 may have a variable relative height with respect to the spin head 2410 so that the inflow hole 2421 of any one recovery container 2430 is disposed on a horizontal surface of the substrate S seated on the spin head 2410. The bracket 2441 is fixed to the recovery container 2430. The bracket 2441 has one end fixed and coupled to the elevation shaft 2442 moved in the third direction Z by the elevator 2443. When the recovery container 2430 is provided in plurality, the bracket 2441 may be coupled to the outermost recovery container 2430. When the substrate S is loaded on the spin head 2410 or unloaded from the spin head 2410, the elevation member 2440 may move the recovery container 2430 downward to prevent the recovery container 2430 from interfering with a path of the transfer robot 2210 for transferring the substrate S.

Also, when a fluid is supplied by the fluid supply part and the spin head 2410 is rotated to perform the first process, the elevation member 2440 may move the recovery container 2430 in the third direction Z to locate the inflow hole 2431 of the recovery container 2430 on the same horizontal plan as the substrate S so that the fluid bouncing from the substrate S by a centrifugal force due to the rotation of the substrate S is recovered. For example, in a case where the first process is performed in an order of the chemical process by the detergent, the cleaning process by the rinsing agent, and the first drying process by the organic solvent, the first, second, and third inflow holes 2431a, 2431b, and 2431c may be moved to the same horizontal plane as the substrate S to recovery the fluids into the first, second, and third recovery containers 2430a, 2430b, and 2430c when the detergent, the rinsing agent, and the organic solvent are supplied, respectively. As described above, when the used fluids are recovered, environmental pollution may be prevented, and also, the expensive fluids may be recycled to reduce the semiconductor manufacturing costs.

The elevation member 2440 may move the spin head 2410 in the third direction Z, instead of moving the recovery container 2430.

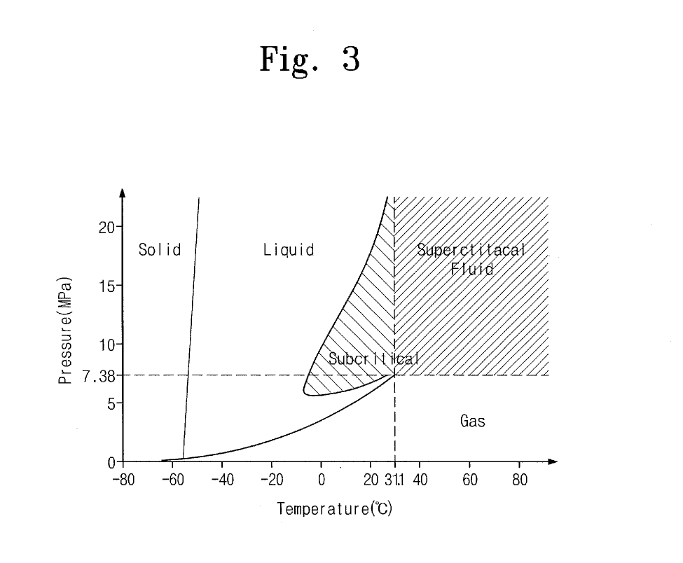

FIG. 3 is a view illustrating a phase transition of carbon dioxide.

A supercritical fluid will be described with reference to FIG. 3.

The supercritical fluid represents a fluid in a state in which a material exceeds a critical temperature and a critical pressure, i.e., a material is not classified into liquid and gaseous states by reaching a critical state. The supercritical fluid has a molecular density similar to that of liquid and viscosity similar to that of gas. Since the supercritical fluid has very high diffusion, penetration, and dissolution, the supercritical fluid has an advantage of chemical reaction. Also, since the supercritical fluid does not exert an interface tension to a fine structure due to a very low surface tension thereof, drying efficiency may be superior when the semiconductor device is dried, and pattern collapse may be prevented.

Hereinafter, a supercritical fluid of carbon dioxide (CO₂) mainly used for drying the substrate S will be described. However, the present invention is not limited to components and kinds of the supercritical fluid.

When carbon dioxide has a temperature of about 31.1° C. or more and a pressure of about 7.38 Mpa or more, the carbon dioxide may become in a supercritical state. The carbon dioxide may be nonpoisonous, nonflammable, and inert properties. Also, the supercritical carbon dioxide has a critical temperature and pressure less than those of other fluids. Thus, the supercritical carbon dioxide may be adjusted in temperature and pressure to easily control dissolution thereof. Also, when compared to water or other solvents, the supercritical carbon dioxide may have a diffusion coefficient less by about 10 times to about 100 times than that of the water or other solvents and a very low surface tension. Thus, the supercritical carbon dioxide may have physical properties suitable for performing the drying process. Also, the carbon dioxide may be recycled from byproducts generated by various chemical reactions. In addition, the supercritical carbon dioxide used in the drying process may be circulated and reused to reduce environmental pollution.

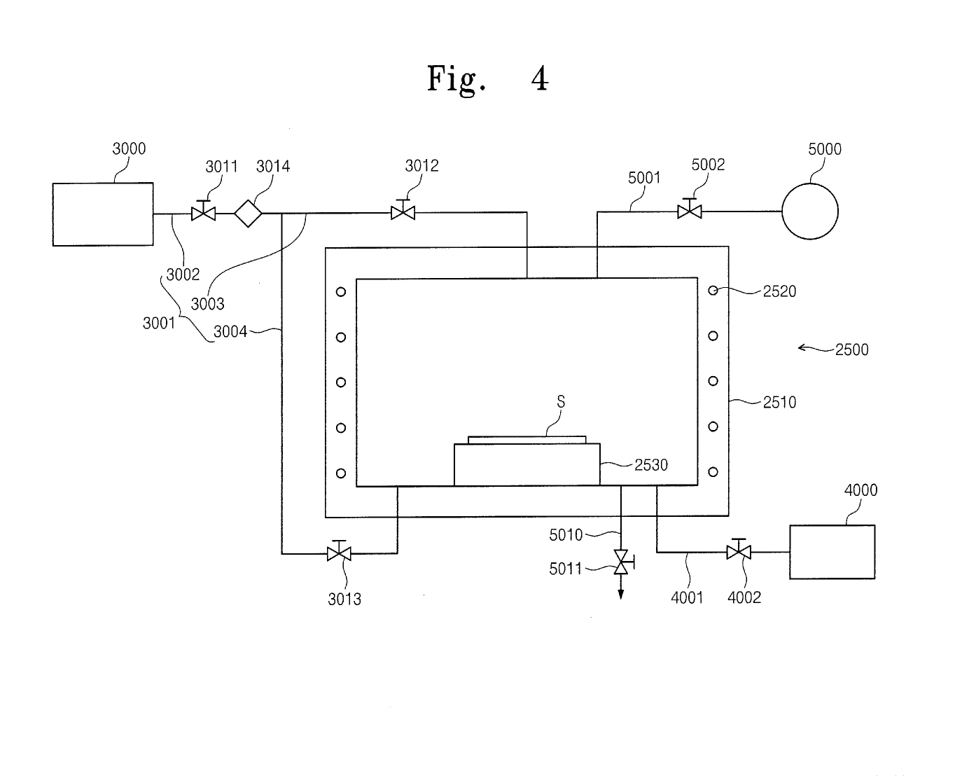

FIG. 4 is a view illustrating a tube of a second process chamber of FIG. 1.

Referring to FIG. 4, the second process chamber 2500 includes a housing 2510, a heating member 2520, and a support member 2530. The second process is performed in the second process chamber 2500. Here, the second process may be a second drying process for drying the substrate S using a supercritical fluid.

The inside of the housing 2510 may provide a space which is sealed from the outside to dry the substrate S. The housing 2510 may be formed of a material enough to endure a high pressure. The heating member 2520 for heating the inside of the housing 2510 may be disposed between an inner wall and an outer wall of the housing 2510. Of cause, the present invention is not limited to a position of the heating member 2520. For example, the heating member 2520 may be disposed at a position different from the above-described position. The support member 2530 supports the substrate S. The support member 2530 may be fixed and installed within the housing 2510. Alternatively, the support member 2530 may not be fixed, but be rotated to rotate the substrate S seated on the support member 2530.

A supercritical fluid supply unit 3000 generates the supercritical fluid. For example, the supercritical fluid supply unit 3000 may apply a temperature greater than a critical temperature and a pressure greater than a critical pressure to carbon dioxide to convert the carbon dioxide into the supercritical fluid. The supercritical fluid generated in the supercritical fluid supply unit 300 is supplied into the housing 2510 through a supply tube 3001.

The supply tube 3001 includes a main tube 3002, an upper supply tube 3003, and a lower supply tube 3004. The main tube 3002 has one end connected to the supercritical fluid supply unit 3000. A branch part 3005 from which the upper supply tube 3003 and the lower supply tube 3004 are branched is disposed on the other end of the main tube 3002. The upper supply tube 3003 has one end connected to the branch part 3005 and the other end connected to an upper portion of the housing 2510. The lower supply tube 3004 has one end connected to the branch part 3005 and the other end connected to a lower portion of the housing 2510. Supply valves 3011, 3012, and 3013 are provided in the supply tube 3001. The main valve 3011 is disposed in the main tube 3002. The main valve 3011 may adjust an opening or closing of the main tube 3002 and a flow rate of supercritical fluid flowing into the main tube 3002. The upper valve 3012 and the lower valve 3013 may be disposed in the upper supply tube 3003 and the lower supply tube 3004, respectively. Each of the upper valve 3012 and the lower valve 3013 may adjust an opening or closing of each of the upper and lower supply tubes 3003 and 3004 and a flow rate of supercritical fluid of each of the upper and lower supply tubes 3003 and 3004. A filter 3014 is disposed between the branch part 3005 and the main valve 3011. The filter 3014 filters foreign substances from the supercritical fluid flowing into the supply tube 3001.

According to another embodiment, the upper supply tube 3003 or the lower supply tube 3004 may be omitted. Also, the supply tube 3001 may have one end connected to the supercritical fluid supply unit 300 and the other end connected to a side surface of the housing 2510.

A discharge tube 4001 discharges the supercritical fluid and gas within the housing 2510 to the outside. The discharge tube 4001 has one end connected to the housing 2510 and the other end connected to a recycling unit 4000. A discharge valve 4002 is disposed in the discharge tube 4001. The discharge valve 4002 opens or closes the discharge tube 4001. Also, the discharge valve 4002 may adjust a flow rate of supercritical fluid flowing into the discharge tube 4001. The supercritical fluid discharged from the housing 2510 is received in the recycling unit 4000. The organic solvent exists on a surface of the substrate S loaded into the housing 2510. When the second drying process is performed, the organic solvent together with the supercritical fluid is discharged into the discharge tube 4001. The recycling unit 4000 removes the organic solvent contained in the supercritical fluid. For example, the supercritical fluid may be supplied into the supercritical fluid supply unit 300 or moved into a container storing the supercritical fluid after the organic solvent is removed therefrom.

A gas supply source 5000 is connected to the housing 2510 through a gas supply tube 5001. A valve 5002 is disposed in the gas supply tube 5001. The valve 5002 opens or closes the gas supply tube 5001. Also, the valve 5002 may adjust a flow rate of inert gas supplied into the housing 2510. The gas supply tube 5001 supplies the inert gas into the housing 2510. The gas supply source 5000 may be a tank storing the inert gas. The inert gas may include N², He, Ne, and Ar. The inert gas may be supplied into the housing 2510 before the supercritical fluid is supplied into the housing 2510. The inert gas supplied into the housing 2510 increases an internal pressure of the housing 2510. For example, the inert gas may be supplied so that the internal pressure of the housing 2510 reaches a critical pressure or more.

An exhaust tube 5010 may be connected to the housing 2510. The inert gas may be exhausted through the exhaust tube 5010. An exhaust valve 5011 is disposed in the exhaust tube 5010. The exhaust valve 5011 opens or closes the exhaust tube 5010. Also, the exhaust valve 5011 may adjust a flow rate of inert gas discharged into the exhaust tube 5010. The supercritical fluid is supplied into the housing 2510 in a state where the internal pressure of the housing 2510 increases by the inert gas. Simultaneously, the inert gas within the housing 2510 is exhausted into the exhaust tube 5010. An amount of inert gas exhausted into the exhaust tube 5010 may correspond to that of supercritical fluid supplied into the supply tube 3001. Thus, the internal pressure of the housing 2510 may be maintained at the critical pressure or more. When the supply of the supercritical fluid and the exhaust of the inert gas are continuous for a predetermined time, the inside of the housing 2510 may be filled with the supercritical fluid.

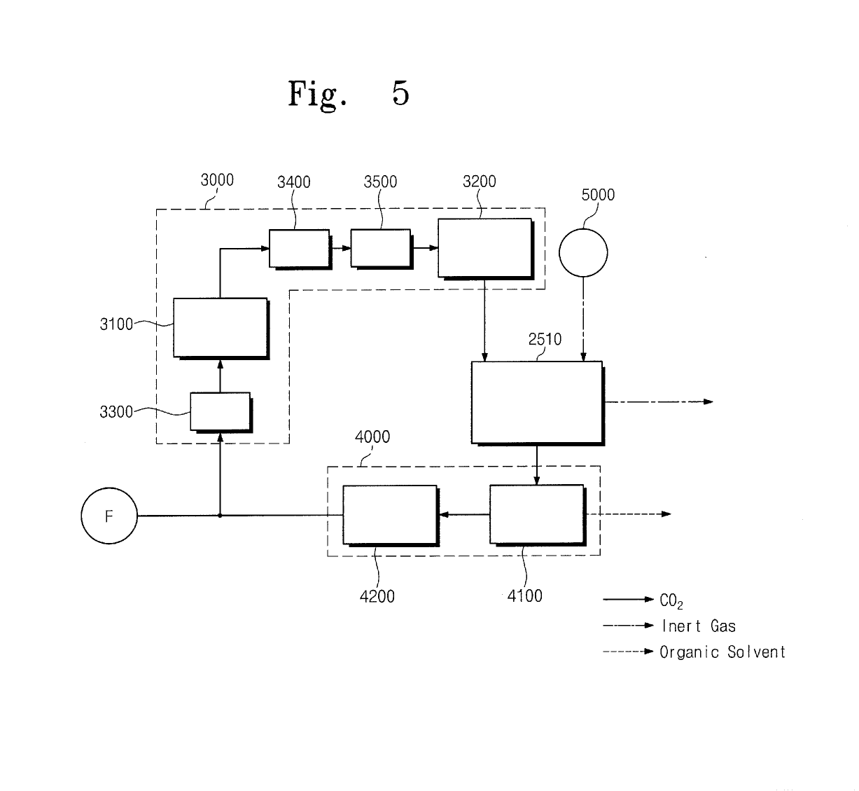

FIG. 5 is a view illustrating circulation of the supercritical fluid.

Referring to FIG. 5, the supercritical fluid may be circulated into the supercritical fluid supply unit 3000, the second process chamber 2500, and the recycling unit 4000.

The supercritical fluid supply unit 3000 may include a storage tank 3100, a conversion tank 3200, a first condenser 3300, a second condenser 3400, and a pump 3500.

Carbon dioxide is stored in the storage tank 3100 in a liquid state. The carbon dioxide may be supplied from the outside or the recycling unit 400 and then stored in the storage tank 3100. Here, the carbon dioxide supplied into the outside or the recycling unit 400 may be in a partial gaseous state. The first condenser 3300 converts the gaseous carbon dioxide into liquid carbon dioxide to supply the liquid carbon dioxide into the storage tank 3100. Since the liquid carbon dioxide has a volume less than that of the gaseous carbon dioxide, a large amount of carbon dioxide may be stored in the storage tank 3100. The first condenser 3300 may be omitted.

The conversion tank 3200 converts the carbon dioxide supplied from the storage tank 3100 into a supercritical fluid to supply the supercritical fluid into the second process chamber 2500. Also, the conversion tank 3200 may temporarily store the carbon dioxide. The carbon dioxide stored in the storage tank 3100 may be moved into the conversion tank 3200 while being converted into a gaseous state when a valve (not shown) connecting the storage tank 3100 to the conversion tank 3200 is opened. Here, the second condenser 3400 and the pump 3500 may be disposed in the line connecting the storage tank 3100 to the conversion tank 3200. The second condenser 3400 converts the gaseous carbon dioxide into the liquid carbon dioxide. The pump 3500 converts the liquid carbon dioxide into gaseous carbon dioxide compressed at a critical pressure or more to supply the gaseous carbon dioxide into the conversion tank 3200. The conversion tank 3200 may heat the supplied carbon dioxide at a critical temperature or more to convert the carbon dioxide into the supercritical fluid, and then transfer the supercritical fluid into the second process chamber 2500. Here, the carbon dioxide discharged from the conversion tank 3200 may be in a state which the carbon dioxide is compressed at a pressure of about 100 bar to about 150 bar. When the liquid or gaseous carbon dioxide is required in the second process chamber 2500 according to the progression of the processes, the conversion tank 3200 may supply the liquid or gaseous carbon dioxide into the second process chamber 2500.

The recycling unit 4000 may include a separation module 4100 and a column module 4200. The recycling unit 4000 separates the organic solvent contained in the supercritical fluid discharged from the housing 2510.

The separation module 4100 cools the carbon dioxide and organic solvent discharged from the housing 2510. During the cooling, the organic solvent is liquefied and thus separated from the carbon dioxide. An absorbent (not shown) absorbing the organic solvent is provided in the column module 4200. The carbon dioxide passing through the separation module 4100 is introduced into the column module 4200. The organic solvent contained in the carbon dioxide is absorbed into the absorbent and then separated.

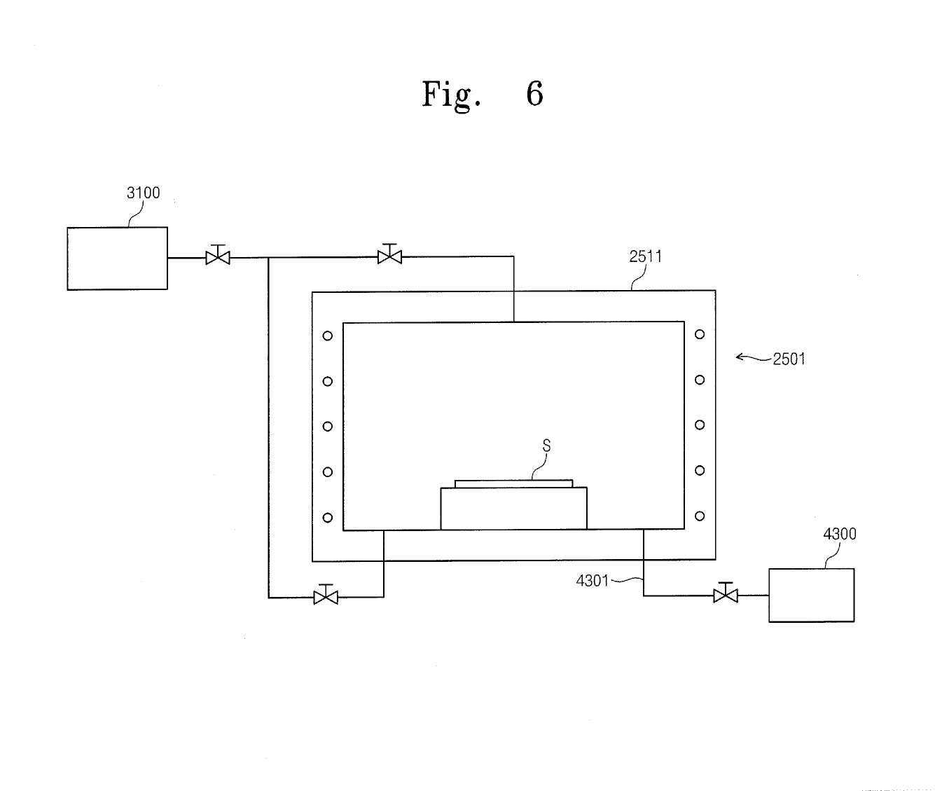

FIG. 6 is a view illustrating tubes of a second process chamber according to another embodiment.

Referring to FIG. 6, the gas supply tube 5001 and the exhaust tube 5010 of FIG. 4 among tubes connected to a second process chamber 2501 may be omitted. A housing 2511, a supercritical fluid supply unit 3100, and a recycling unit 4300 may have the same constitution as those of the second process chamber 2500 illustrated in FIG. 4. Also, the recycling unit 4300 may be omitted. Here, a supercritical fluid discharged into a discharge tube 4301 is wasted.

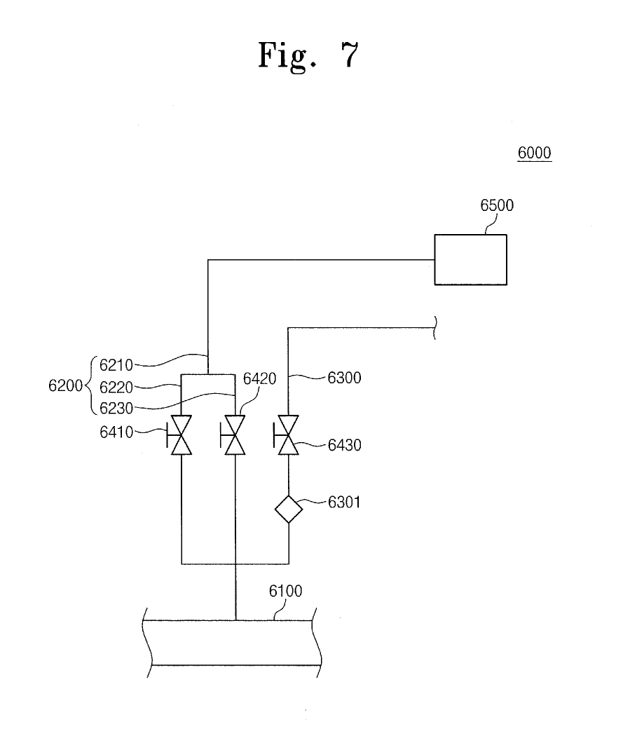

FIG. 7 is a view of a vent unit according to an embodiment of the present invention.

Referring to FIG. 7, a vent unit 6000 includes a recovery tube 6200 and a waste tube 6300.

A supercritical fluid may be stored in a container 6100. Also, the supercritical fluid flows into the container 6100. The first condenser 3300, the storage tank 3100, the second condenser 3400, the pump 3500, and the conversion tank 3200 which are included in the supercritical fluid supply unit 3000 of FIGS. 4 and 5 and the tubes connecting the storage tank 3100, the second condenser 3400, the pump 3500, and the conversion tank 3200 to each other may constitute the container 6100. Also, tubes connecting the supercritical fluid supply unit 3000, the housing 2510, and the recycling unit 4000 to each other may constitute the container 6100.

A recovery tube 6200 connects the container 6100 to a recovery container 6500. A main recovery tube 6210 has one end connected to the recovery container 6500. The main recovery tube 6210 may have the other end branched in parallel into a first line 6220 and a second line 6230. Ends of the first and second lines 6220 and 6230 are connected to the container 6100. The ends of the first and second lines 6220 and 6230 may be combined with each other and then connected to the container 6100. Also, each of the first and second lines 6220 and 6230 may be connected to the container 6100. Here, portions at which the first and second lines 6200 and 6230 are connected to the container 6100 may be disposed adjacent to each other. A first valve 6410 and a second valve 6420 may be disposed in the first line 6220 and the second line 6230, respectively.

The first valve 6410 may be set to be opened so that the supercritical fluid within the container 6100 reaches a predetermined temperature or pressure. When the supercritical fluid within the container 6100 has a temperature or pressure greater than a preset temperature or pressure, the supercritical fluid is discharged through the recovery tube 6200. Thus, it may prevent the temperature or pressure of the container 6100 from increasing than the preset temperature or pressure. Also, the first valve 6410 may be opened when power supplied into the substrate treating apparatus 100 is blocked. When power is not supplied into the substrate treating apparatus 100, the temperature or pressure of the container 6100 may increase because the state of the supercritical fluid received in the container 6100 is not controlled. The supercritical fluid of which the state is not controlled is discharged through the first line 6220 to prevent the container 6100 from increasing in pressure or temperature in the state where the supply of power is blocked. For convenience of the control of the first valve 6410, the first valve 6410 may be opened or closed by using a gas.

The second valve 6420 opens or closes the second line 6230. Also, the second valve 6420 may adjust an amount of supercritical fluid flowing into the second line 6230. The second valve 6420 may be manually opened or closed by a worker. Also, the second valve 6420 may be connected to a control unit (not shown). Thus, the opening or closing of the second valve 6420 may be controlled by the control unit. While the substrate treating apparatus 100 is used, the container 6100 may be maintained or repaired. The maintenance or repair of the container 6100 may be performed after the supercritical fluid received in the container 6100 is discharged through the second line 6230. The valves 6410 and 6420 disposed in the recovery tube 6200 may be provided in a diaphram type. When the valves 6410 and 6420 are provided in the diaphram type, introduction of the foreign substances into the supercritical fluid flowing into the valves 6410 and 6420 may be prevented or reduced. The first and second valves 6410 and 6420 may be connected to the first and second lines 6220 and 6230 in a cleaning fitting manner, respectively. For example, the first and second valves 6410 and 6420 may be connected to the first and second lines 6220 and 6230 in a metal seal fitting manner, respectively. Thus, when the supercritical fluid passes through the first or second valve 6410 or 6420, the foreign substances are not introduced into the supercritical fluid through a junction part of the valve, or an amount of foreign substances introduced into the supercritical fluid decreases. The supercritical fluid collected in the recovery container 6500 may be reused. When an amount of foreign substance contained in the supercritical fluid collected in the recovery container 6500 is less than a predetermined amount, the supercritical fluid may be reused immediately. For example, the recovery container 6500 may be connected to the supercritical fluid supply unit 3000 through a tube (not shown) to supply the supercritical fluid into the supercritical fluid supply unit 3000. Also, an amount of foreign substances contained in the supercritical fluid is greater than a predetermined amount, the supercritical fluid may be reused after the foreign substances are filtered from the supercritical fluid. For example, the recovery container 6500 may be connected to a foreign substance separation device (not shown) through a tube. Also, the recovery container 6500 may be provided as a device that is capable of separating the foreign substances contained in the supercritical fluid received in the recovery container 6500.

The waste tube 6300 has one end connected to the container 6100. For example, the waste tube 6300 may be directly connected to the container 6100. Also, the waste tube 6300 may be combined with the first or second line 6220 or 6230 and then connected to the container 6100. Here, the waste tube 6300 may be combined with the first or second line 6220 or 6230 on a side opposite to the main recovery tube 6210 with respect to the first or second valve 6410 or 6420. The other end of the waste tube 6300 may be configured to discharge the supercritical fluid to the atmosphere or connected to a water tank (not shown) in which a supercritical fluid to be wasted is temporarily stored.

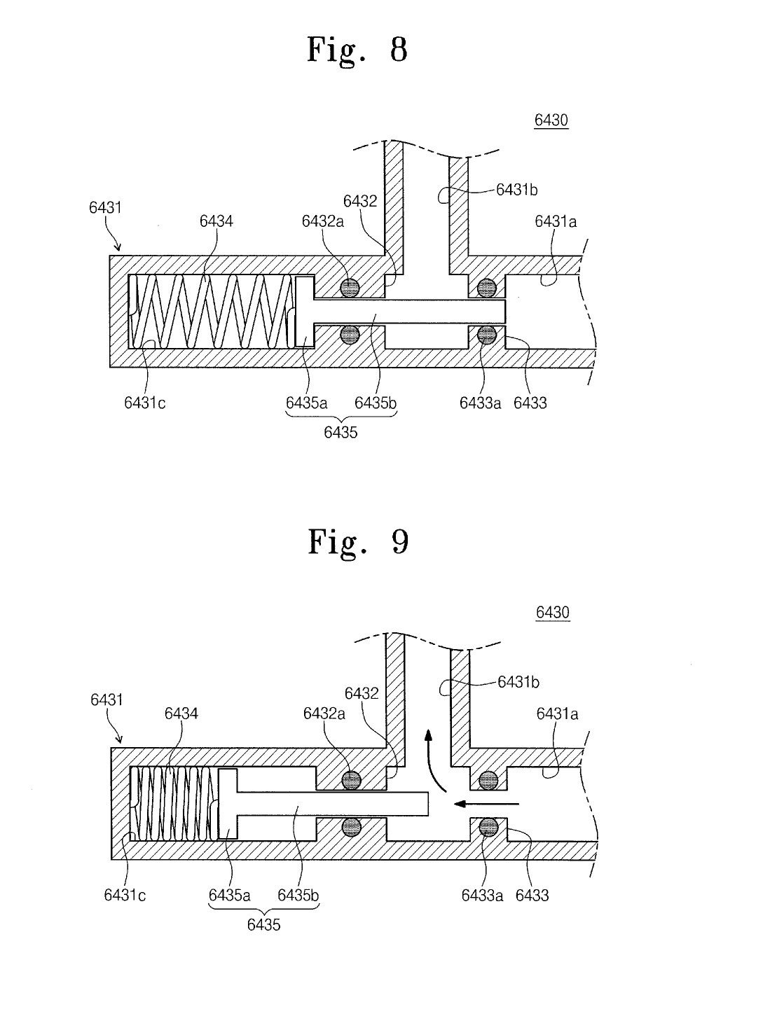

FIG. 8 is a cross-sectional view of a safety valve.

Referring to FIGS. 7 and 8, a safety valve 6430 includes a valve housing 6431, an elastic member 6434, and a piston 6435. The safety valve 6430 is disposed in the waste tube 6300. The safety valve 6430 may be automatically opened when an internal pressure of the container 6100 is greater than a predetermined pressure.

The valve housing 6431 defines an outer appearance of the safety valve 6430. An inlet 6431a and an outlet 6431b are disposed in the valve housing 6431. Each of the inlet 6431a and the outlet 6431b is connected to the waste tube 6300. A cylinder 6431c is disposed on a side opposite to the inlet 6431a in the valve housing 6431. The elastic member 6434 is disposed in the cylinder 6431c.

A piston 6435 includes a press plate 6435a and a rod 6435b. The press plate 6435a is disposed in the cylinder 6431c between a first sealing part 6432 and the elastic member 6434. Sealing parts 6432 and 6433 preventing the supercritical fluid from leaking between the piston 6435 and the valve housing 6431 may be disposed in the valve housing 6431. For example, the first sealing part 6432 stepped to have a section less than that of the cylinder 6431c may be disposed on a front side of the cylinder 6431c, and the second sealing part 6433 stepped to have a section less than that of the inlet 6431a may be disposed on a front side of the inlet 6431a. The rod 6435b extends from one surface of the press plate 6435a and is disposed on the first and second sealing parts 6432 and 6433. Packings 6432a and 6433a preventing the supercritical fluid from leaking between the valve housing 6431 and the piston 6435 may be disposed on an inner wall of the valve housing 6431. For example, the first packing 6432a and the second packing 6433a may be disposed on the first sealing part 6432 and the second sealing part 6433, respectively. The first or second packing 6432a or 6433a may be formed of rubber. For example, the first or second packing 6432a or 6433a may be formed of a material containing viton. Each of the first packing 6432a and the second packing 6433a may prevent the supercritical fluid from leaking between the first sealing part 6432 and the second sealing part 6433.

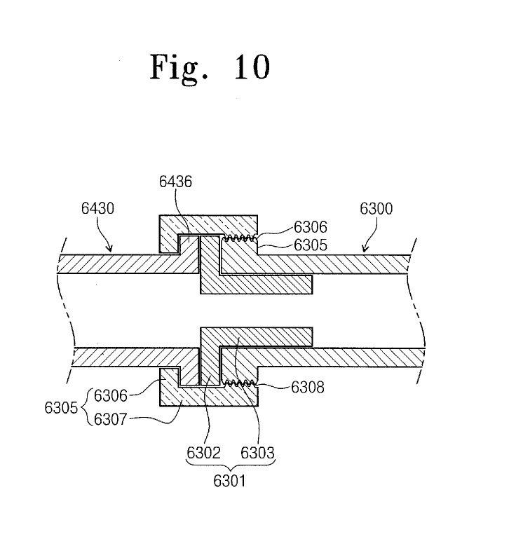

FIG. 9 is a view of a state in which the safety valve is opened.

A process of opening the safety valve 6430 will be described with reference to FIG. 9.

A pressure due to the supercritical fluid is applied to an end of the rod 6435b. When the pressure applied to the rod 6435b is greater than that applied to the press plate 6435a by the elastic member 6434, the piston 6435 may move toward the cylinder 6431c to open the safety valve 6439. As a result, the supercritical fluid may flow from the inlet 6431a to the outlet 6431b. The flowing supercritical fluid contacts the second packing 6433a. The second packing 6433a may be dissolved while contacting the supercritical fluid to contaminate the supercritical fluid. Also, when the piston 6435 is reciprocated, foreign substances may be generated on the elastic member 6434, the first packing 6432a, and the second packing 6433a. Also, a portion of the supercritical fluid may be introduced into the first sealing part 6432 or the cylinder 6431c to dissolve the first packing 6432a or the elastic member 6434, thereby generating foreign substances. The foreign substances may contaminate the supercritical fluid passing through the safety valve 6430. Thus, a relatively large amount of foreign substances may be contained in the supercritical fluid passing through the safety valve 6430 when compared to the supercritical fluid introduced into the recovery container 6500 through the recovery tube 6200.

A filter 6301 is disposed in the waste tube 6300 between the container 6100 and the safety valve 6430. The supercritical fluid existing in an inlet-side may be introduced toward the container 6100. The supercritical fluid existing in the inlet-side may contain foreign substances due to the first packing 6432a, the second packing 6433a, or the elastic member 6434. Thus, the filter 6301 may filter the foreign substances contained in the supercritical fluid introduced from the inlet-side toward the container 6100 to prevent the supercritical fluid within the container 6100 from being contaminated.

FIG. 10 is a cross-sectional view of a portion at which the safety valve and the water tube are connected to each other.

Referring to FIG. 10, the filter 6301 may be provided in a gasket type.

The filter 6301 includes a gasket part 6302 and a filter part 6303. The gasket part 6302 may have a tube shape corresponding to that of each of ends of the safety valve 6430 and the waste tube 6300. For example, when the end of each of the safety valve 6430 and the waste tube 6300 has a circular shape, the gasket part 6302 may have a ring shape. The filter part 6303 extends from a side surface of the gasket part 6302. The filter part 6303 may be disposed on one side surface or both side surfaces of the gasket part 6302. The filter part 6303 is inserted into the waste tube 6300 or the safety valve 6430 and then fixed.

The safety valve 6430 and the waste tube 6300 in which the filter 6301 is inserted are fixed by using a coupling member 6305. The coupling member 6305 includes a first coupling part 6306 and a second coupling part 6307. The first coupling part 6306 may have a ring shape corresponding to that of an outer circumferential surface of the safety valve 6430. The second coupling part 6307 extends from a side surface of the first coupling part 6306. A screw thread 6308 is disposed on an inner circumferential surface of the second coupling part 6307. A first protrusion 6436 and a second protrusion 6305 which protrude in a radius direction are disposed on an outer circumferential surface of the safety valve 6430 and an outer circumferential surface of the waste tube 6300. A screw thread 6306 is disposed on an outer circumferential surface of the second protrusion 6305. The first coupling part 6306 is fixed to a side surface of the first protrusion 6436. The second coupling part 6307 and the second protrusion 6305 are engaged with the screw threads 6305 and 6308 and thus fixed with respect to each other. According to another embodiment, a screw thread may be disposed on the first protrusion 6436. The first coupling part 6306 may be fixed to a side surface of the second protrusion 6305, and the screw thread 6308 disposed on the second coupling part 6307 may be engaged with the screw thread disposed on the first protrusion 6436, and thus, the second coupling part 6307 and the first protrusion 6436 may be fixed to each other.

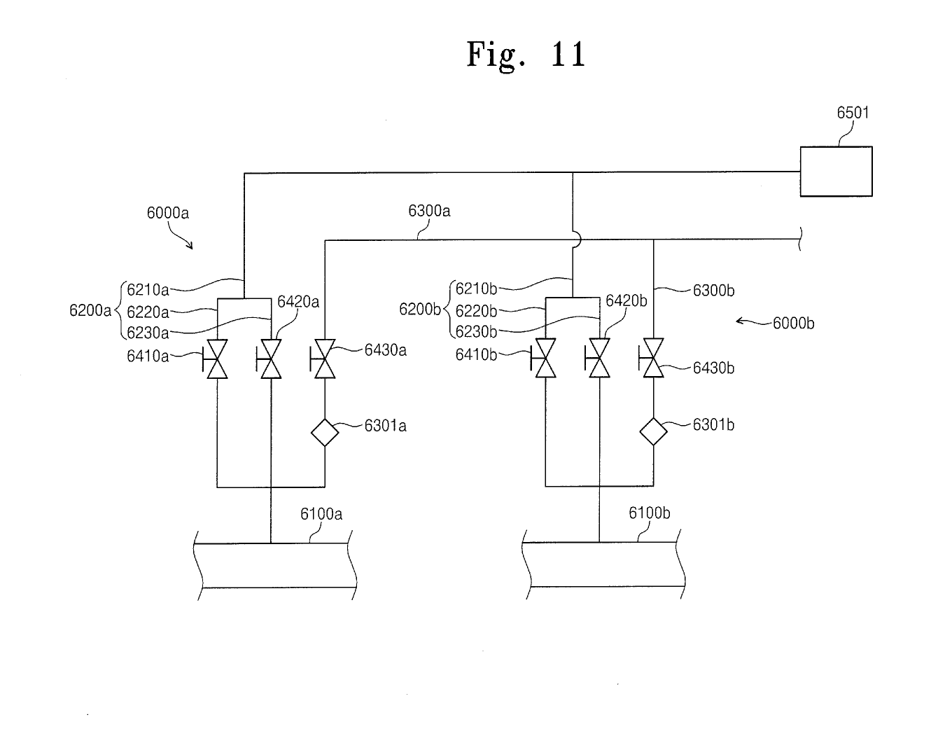

FIG. 11 is a view of a state in which the vent unit is connected.

Referring to FIG. 11, the substrate treating apparatus includes a plurality of vent units 6000a and 6000b.

The first vent unit 6000a and the second vent unit 6000b are connected to a first container 6100a and a second container 6100b, respectively. Each of the first container 6100a and the second container 6100b may be one of the first condenser 3300, the storage tank 3100, the second condenser 3400, the pump 3500, and the conversion tank 3200 which are included in the supercritical fluid supply unit 3000 and the tubes connecting the storage tank 3100, the second condenser 3400, the pump 3500, and the conversion tank 3200 to each other. Also, each of the first container 6100a and the second container 6100b may be one of the tubes connecting the supercritical fluid supply unit 3000, the housing 6431, and the recycling unit 4000 to each other. Each of a recovery tube 6200a and a waste tube 6300a which are included in the first vent unit 600a and a recovery tube 6200b and a waste tube 6300b which are included in the second vent unit 6000b may be the same as the vent unit 6000 of FIG. 7. Also, main recovery tubes 6210a and 6210b, first lines 6220a and 6220b, second lines 6230a and 6230b, first valves 6410a and 6410b, second valves 6420a and 6420b, and third valves 6430a and 6430b which respectively are inclined in the first vent unit 600a and the second vent unit 600b may have the same constitution as that of the vent unit 6000 of FIG. 7.

The first valve 6410a of the first vent unit 6000a and the first valve 6410b of the second vent unit 6000b may be opened at the same temperature or different temperatures. Also, the safety valve 6430a of the first vent unit 6000a and the safety valve 6430b of the second vent unit 6000b may be opened at the same temperature or different temperatures.

Each of the recovery tube 6200a of the first vent unit 6000a and the recovery tube 6200b of the second vent unit 6000b may be connected to a recovery container 6501, or the recovery tube 6200a of the first vent unit 6000a and the recovery tube 6200b of the second vent unit 6000b may be combined with each other and then connected to the recovery container 6501. The waste tube 6300a of the first vent unit 6000a and the waste tube 6300b of the second vent unit 6000b may be combined with each other and then exhaust a supercritical gas to the atmosphere or be connected to a waste tank. Also, each of the waste tube 6300a of the first vent unit 6000a and the waste tube 6300b of the second vent unit 6000b may exhaust the supercritical gas to the atmosphere or be connected to the waste tank.

The foregoing detailed descriptions may be merely an example of the prevent invention. Having now described exemplary embodiments, those skilled in the art will appreciate that modifications may be made to them without departing from the spirit of the concepts that are embodied in them. Further, it is not intended that the scope of this application be limited to these specific embodiments or to their specific features or benefits. Rather, it is intended that the scope of this application be limited solely to the claims which now follow and to their equivalents.

According to the embodiments of the present invention, the supercritical fluid discharged from the container may be separated and collected according to a degree of contamination.

Also, according to the embodiments of the present invention, the supercritical fluid discharged from the container may have improved recycling efficiency.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An substrate treating apparatus comprising:
a container providing a space in which a supercritical fluid flows or is received;
a recovery tube having one end connected to the container to discharge the supercritical fluid within the container, the recovery tube comprising a valve; and
a waste tube connected to the container to discharge the supercritical fluid within the container, the waste tube comprising a safety valve,
wherein the recovery tube having the other end connected to a recovery container in which the supercritical fluid discharged from the container is received for reusing.

2. The substrate treating apparatus of claim 1, wherein the valve of the recovery tube is different from the safety valve of the waste tube.

3. The substrate treating apparatus of claim 1, wherein the safety valve comprises:
a valve housing connected to the waste tube, the valve housing comprising an inlet through which the supercritical fluid is introduced and an outlet through which the supercritical fluid is discharged;
an elastic member disposed in a cylinder that is provided within the valve housing; and
a piston disposed between the elastic member and the inlet to open or close the safety valve while moving by the elastic member or a pressure of the supercritical fluid.

4. The substrate treating apparatus of claim 3, wherein a packing preventing the supercritical fluid from leaking between the piston and an inner wall of the valve housing is disposed on the inner wall of the valve housing.

5. The substrate treating apparatus of claim 4, wherein the packing comprises a viton.

6. The substrate treating apparatus of claim 1, wherein the valve disposed in the recovery tube is provided in a diaphram type.

7. The substrate treating apparatus of claim 1, wherein the recovery container separates foreign substances from the supercritical fluid received therein.

8. The substrate treating apparatus of claim 1, wherein the recovery container is connected to a supercritical fluid supply unit that supplies the supercritical fluid into a housing providing a space in which a substrate is treated.

9. The substrate treating apparatus of claim 1, wherein the recovery tube comprises:
a main recovery tube having one end connected to the recovery container; and
first and second lines branched from the other end of the main recovery tube in parallel, the first and second lines each being connected to the container.

10. The substrate treating apparatus of claim 9, wherein the valve comprises a first valve disposed in the first line and a second valve disposed in the second line.

11. The substrate treating apparatus of claim 1, wherein the container comprises a housing providing a space in which a substrate is treated.

12. The substrate treating apparatus of claim 1, wherein the container comprises a supercritical fluid supply unit that supplies the supercritical fluid into a housing providing a space in which a substrate is treated.

13. The substrate treating apparatus of claim 1, wherein the container comprises a tube connecting a housing providing a space in which a substrate is treated to a supercritical fluid supply unit that supplies the supercritical fluid into the housing.
